(19) United States
(12) Patent Application Publication
(10) Pub. No.: US 2026/0291513 A1
(43) Pub. Date: Sep. 24, 2026

(54) MULTI-CHANNEL SPECTRUM ANALYZER IMPLEMENTING NOISE FEATURES PERFORMANCE FOR MULTIPLE BANDWIDTH CAPACITIES

(71) Applicant: VIAVI SOLUTIONS INC., Chandler, AZ (US)

(72) Inventors: Bon-Jin KU, Seoul (KR); Seung-Gon HONG, Seoul (KR)

(73) Assignee: VIAVI SOLUTIONS INC., Chandler, AZ (US)

(21) Appl. No.: 19/087,978

(22) Filed: Mar. 24, 2025

(51) Int. Cl. H03M 1/12; H04B 17/00

(52) U.S. Cl. CPC H03M 1/122; H04B 17/0085

(57) ABSTRACT

A multi-channel analog-digital converter (ADC) subsystem for test device such as a spectrum analyzer may include multiple multi-channel ADCs to receive one or more down-converted signals from a mixer of a test device, convert, by a noise performance component, the one or more down-converted signals from the mixer to one or more down-converted, noise performance-adjusted signals, select, by a field programmable gate array (FPGA) of the test device, one or more analog-digital converters (ADCs) among a plurality of ADCs, and convert the one or more down-converted, noise performance-adjusted signals to digital output signals using the selected one or more ADCs.

### TECHNICAL FIELD

This patent application is directed to spectrum analyzers, and more specifically, to spectrum analyzer testing devices implementing noise performance techniques for multiple bandwidth capacities.

### BACKGROUND

A cell site, also known as a cell tower or cellular base station, includes an antenna and electronic communications equipment to support cellular mobile device communication. The antenna and equipment are typically placed in connection with a radio mast or tower, and the equipment generally connects cell site air interfaces to wireline networks, which may be comprised of fiber optic cables and coaxial cables. When setting up or maintaining a cell site, technicians may utilize, among other test devices, spectrum analyzers, typically portable spectrum analyzers, to test signal strength, frequency, phase, interference, etc.

At a cell site, there may be a variety of signals depending on technology, e.g., 4G Long Term Evolution (LTE), 5G New Radio (NR), Dynamic Spectrum Sharing (DSS), etc. When configuring instruments to evaluate RF performance in these environments, noise associated with a detected signal may often adversely affect measurements. As a result, depending on the configuration of the spectrum analyzer, accurate analysis may be a challenge.

### BRIEF DESCRIPTION OF DRAWINGS

Features of the present disclosure are illustrated by way of example and not limited in the following Figure(s), in which like numerals indicate like elements, in which:

FIG. 1 illustrates a diagram of a test device in a test environment, according to examples described herein.

FIG. 2 illustrates a block diagram of major components of the test device including a multi-channel ADC subsystem managed by a field programmable gate array (FPGA), according to examples described herein.

FIG. 3 illustrates a diagram of the multi-channel ADC subsystem managed by the FPGA, according to examples described herein.

FIG. 4 illustrates a diagram of the multi-channel ADC subsystem managed by the FPGA with an adjustable ADC sample clock, according to examples described herein.

FIG. 5A illustrates a block diagram of major components of a test device including a noise performance component, according to examples described herein.

FIG. 5B illustrates a block diagram of major components of a test device including a noise performance component, according to examples described herein.

FIG. 5C illustrates a block diagram of major components of a test device including a noise performance component, according to examples described herein.

FIG. 5D illustrates a chart indicating mitigation of a noise level as provided by a noise performance component, according to examples described herein.

FIG. 6 illustrates a flow chart of a method for employing a multi-channel ADC subsystem managed by an FPGA in a spectrum analyzer, according to examples described herein.

FIG. 7 illustrates a block diagram of the test device, according to examples described herein.

### DETAILED DESCRIPTION

For simplicity and illustrative purposes, the present disclosure is described by referring mainly to examples and embodiments thereof. In the following description, numerous specific details are set forth in order to provide a thorough understanding of the present disclosure. It will be readily apparent, however, that the present disclosure may be practiced without limitation to these specific details. In other instances, some methods and structures readily understood by one of ordinary skill in the art have not been described in detail so as not to unnecessarily obscure the present disclosure. As used herein, the terms “a” and “an” are intended to denote at least one of a particular element, the term “includes” means includes but not limited to, the term “including” means including but not limited to, and the term “based on” means based at least in part on.

As mentioned herein, when performing test and analysis for cell site equipment RF technicians may need spectrum analyzers and similar test devices that can process multiple input signals with different frequencies, bandwidths, and types. For example, one signal may be a cellular network signal in GHz bandwidth having a first noise profile, while another signal may be a lower frequency, low bandwidth signal having a second noise profile. Because of associated varying noise profiles, a multi-channel ADC may not enable optimum performance for all input signals.

Along with two or more input signals with different frequencies, bandwidths, and/or signal types, the test device may also receive a user selection for frequency, bandwidth, and/or signal type of the received input signals. A frequency of the input signal, as used herein, may refer to a center frequency of the signal with the bandwidth (i.e., bandwidth of channel) centered around the frequency.

A signal type, also referred to as “technology”, may refer to a category of signal. For example, the signal may be a 4G LTE, 5G NR, 6G, DSS, LTE-FDD, LTE-TDD, NR, DSS-FDD, DSS-TDD signal, where FDD is frequency division duplex and TDD is time division duplex. The signal type may be associated with a specific set of center frequencies and bandwidths, along with a modulation of the signal.

The systems and methods described herein may implement noise performance techniques for multiple bandwidth capacities in testing devices. The testing devices described herein may be directed signal and spectrum analysis, and may be directed to various communication protocols (e.g., LTE, 5G, etc.). The systems and methods described herein may be implemented to, among other things, provide low(er) noise level(s) for signals to converted from analog to digital (e.g., via an ADC).

In some examples, as will be discussed in further detail below, the systems and methods described herein may implement one or more amplifier and/or baluns may be implemented for low, middle, and high frequencies ranges. As generally understood and/or as described herein, a balun may, in some examples, be a logic component that may interface balanced and unbalanced signals without disrupting their impedance. In some examples, baluns implemented in examples described herein may help to reduce noise by isolating unwanted radio frequency (RF) interference.

In some examples and as discussed further below, the input signals may be down-converted at a mixer, and the down-converted signals provided to the multi-channel ADC subsystem. As used herein, down-conversion may refer to the process of mixing a carrier signal (center frequency of the input signal) with a local oscillator signal to create an intermediate frequency (IF) signal for ease of processing, circuit implementation, and accuracy in processing the down-converted signal.

The analog IF signal may then be digitized by one or more analog digital converters (ADCs) for digital processing by downstream circuitry. An FPGA managing the multi-channel ADC subsystem may select one or more suitable ADCs based on the input signal characteristics (frequency, bandwidth, signal type) and ADC characteristics (resolution, SINAD, ENOB, SNR, THD, THD+N, and/or SFDR) to optimize analog-digital conversion and an overall performance of the test device. A central processing unit (CPU) of the test device or the FPGA itself may also set/adjust an ADC sample clock circuit to provide appropriate clock signals to the selected ADC(s). The selected ADC(s) may then perform the conversion, and may provide the digital output signals to other circuits and subsystems of the test device through the FPGA for further processing and/or test and analysis related functionalities.

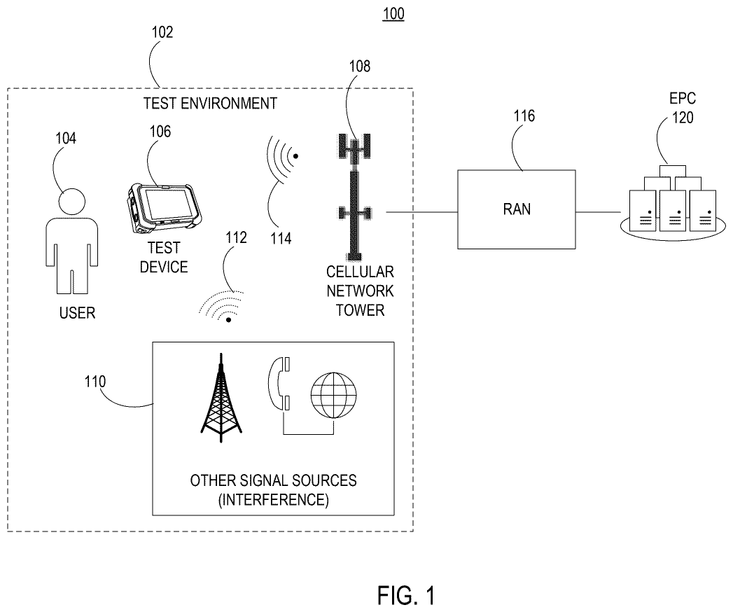

FIG. 1 illustrates a diagram 100 of a test device 106 in a test environment 102, according to examples described herein. As shown in the diagram 100, a user 104 may use a test device 106 to test and analyze signals 114 from a cellular network tower 108, as well as other signals 112, which may come from other signal sources 110 such as a radio tower, telecom signals, and others, which may interfere with the signals 114 from the cellular network tower 108. The cellular network tower 108 may be part of a cell site and connected to backhaul via a radio access network (RAN) 116 and the backhaul may connect to Evolved Packet Core (EPC) 120.

A connection between the cellular network tower 108 and the rest of the world may be referred to as a backhaul link or simply backhaul. A backhaul may include wired, fiber optic and wireless components, such as microwave transmission equipment. In conventional 3G and 4G architectures, fronthaul is associated with a RAN 116 architecture including centralized base band units (BBUs), i.e., baseband controllers, and standalone remote radio heads (RRHs) installed at remote cell sites.

In some instances, the RRH and BBU are at the same location. In other instances, the RRH is located at the cell site, whereas the BBU is located in a centralized and protected location where it serves multiple RRHs. The optical links that interconnect the BBU and the multiple RRHs are referred to as fronthaul. The fronthaul includes interfaces between the RRH and the BBU. The backhaul includes interfaces between the BBU and the EPC 120.

In an example, the test environment 102 may include the cell site, which includes the cellular network tower 108 or cellular base station having antennas and electronic communications equipment to support cellular mobile device communication. The antennas and equipment are typically placed in connection with a radio mast or tower, and the equipment generally connects cell site air interfaces to wireline networks, which may be include fiber optic cables and coaxial cables.

The RAN 116 is the part of a mobile network that connects end-user devices, like smartphones, to the cloud. This is achieved by sending information via radio waves from end-user devices to transceivers of the RAN 116, and finally from the transceivers to the core network which connects to the global internet.

Diagram 100 shows the test device 106 performing signal analysis. In an example use case, testing may be performed when the cell site is being installed, such as to ensure proper operation of the cell site with user devices, such as smartphones or other end user cellular devices.

Carrier frequencies of available channels for one or more technologies may also be detected automatically or by the user 104. The carrier frequencies may be a center frequency and/or a synchronization signal block (SSB) frequency depending on the technology. The technologies may include, but are not limited to, 4G LTE, 5G NR, and DSS. Additional examples of the technologies may include LTE-FDD, LTE-TDD, NR, DSS-FDD, DSS-TDD where FDD is frequency division duplex and TDD is time division duplex.

Accurate testing and analysis of network signals and any interfering signals may improve overall performance of a communications network. When configuring instruments to evaluate the RF performance of the channel under test in these environments, noise associated with a detected signal (e.g., an RF input signal) may often adversely affect measurements. As a result, depending on the configuration of the spectrum analyzer, accurate analysis of detected signals may be a challenge.

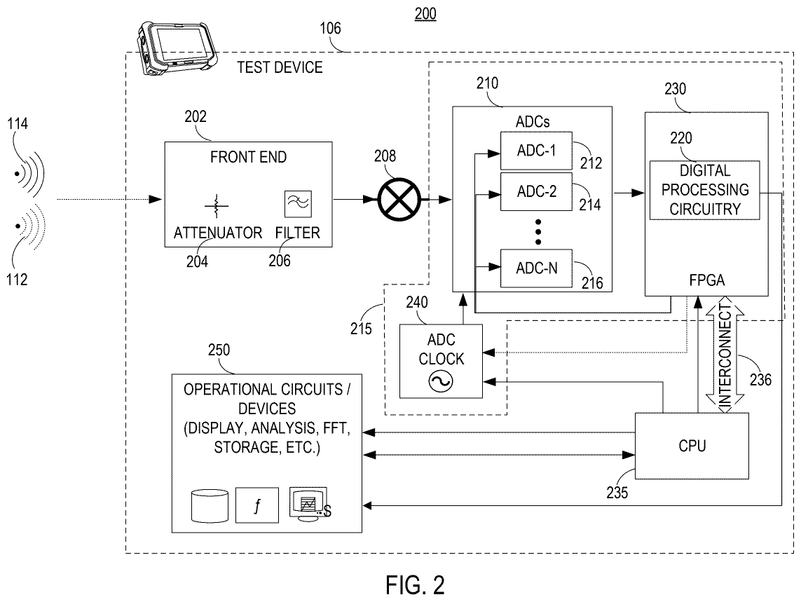

FIG. 2 illustrates a block diagram 200 of major components of the test device 106, according to examples described herein. As block diagram 200 shows, the signals 114 (from the cellular network tower 108) and the other signals 112, which may be interference signals, may be input to the test device 106 and pre-processed by a front end 202. The front end 202 may include, among other circuits and subsystems, an attenuator 204 and a filter 206. The attenuated and filtered signal (pre-processed RF signal) may be down-converted at a mixer 208, and the down-converted signal provided to ADCs 210 of a multi-channel ADC subsystem 215.

The multi-channel ADC subsystem 215 may include any number of multi-channel ADCs 210, such as ADC-1 212, ADC-2, 214, to ADC-N 216, a field programmable gate array (FPGA) 230, and an ADC sample clock 240. The ADCs 210 may receive one or more clock signals from the ADC sample clock 240 to sample the input signal(s) and convert them to digital outputs. A CPU 235 may manage one or more components of the test device 106 such as ADC sample clock 240, FPGA 230, and at least some of the operational circuits and devices 250 (also referred to as operational subsystems).

In some examples, the multi-channel ADC subsystem 215 may be managed, that is, suitable ADCs selected for analog-digital conversion of input signals, by the FPGA 230. Digital output of the selected ADCs may be provided to digital processing circuitry 220, which may be partially or wholly implemented in the FPGA 230. The digital processing circuitry 220 may include detectors, normalizers, filters, etc. Digitally processed signals may be provided by the multi-channel ADC subsystem 215 to operational circuits and devices 250, which may perform analytical operations such as displaying the signals, fast Fourier transforms (FFTs), storing the signals and/or analysis results, and similar operations. Thus, the operational circuits and devices 250 may include an analysis subsystem, a display subsystem, an FFT subsystem, a storage subsystem, and comparable subsystems and circuits.

In some examples, the CPU 235 may communicate with other components over various interfaces and control their operations. For example, the CPU 235 may control the ADC sample clock 240 and set clock frequencies to be provided to ADCs. The ADC sample clock 240 may alternatively be controlled by the FPGA 230. The CPU 235 and the FPGA 230 may also communicate over a peripheral component interconnect (PCI) interface (or interconnect 236). For example, processed (spectrum-analyzed) data may be transmitted by the FPGA 230 to the CPU 235 to be further processed and/or displayed.

As mentioned herein, the test device 106 may be a spectrum analyzer (for example, a portable spectrum analyzer to be used in the field) and may include additional circuitry and subsystems such as a voltage-controlled oscillator (VCO), additional filters, mixers, oscillators, a frequency synthesizer, and so on. Thus, the analog input signal(s) may be processed by any number of analog processing circuitry and the digital signals converted by the multi-channel ADC subsystem 215 may be processed by any number of digital processing circuitry.

It should be appreciated that FIG. 2 shows a simplified block diagram of major components of the test device 106. A test device such as a spectrum analyzer may be implemented with additional of fewer components, where certain functionality may be distributed among various components and sub-systems or performed by additional components or sub-systems. Furthermore, the test device 106 may be any RF test device including, but not limited to, a spectrum analyzer, a cellular system monitoring device, an RF power analyzer, etc.

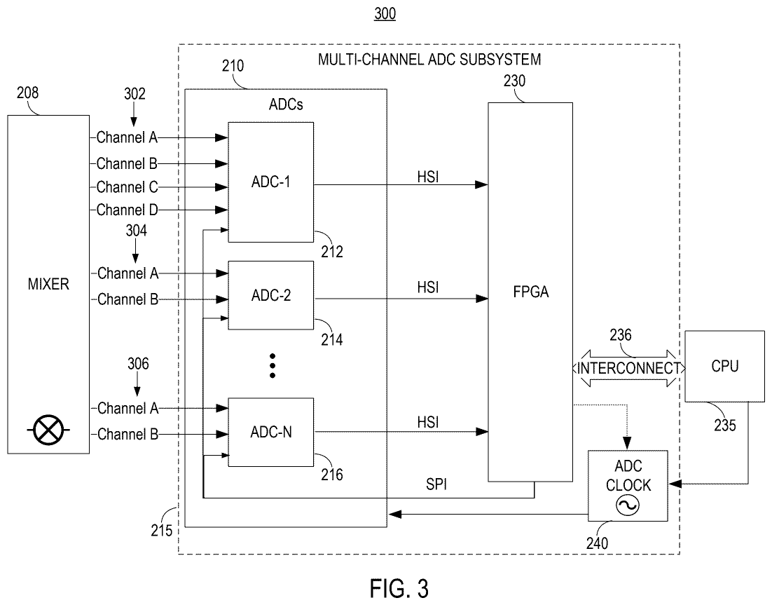

FIG. 3 illustrates a diagram 300 of the multi-channel ADC subsystem 215 managed by the FPGA 230, according to examples described herein. The multi-channel ADC subsystem 215 and its components may be used with similar components shown in FIG. 2. As shown in diagram 300, multiple input signals may be received at a multiple channel test device (spectrum analyzer) and corresponding down-converted signals may be forwarded by the mixer 208 to one or more ADCs 210 in the multi-channel ADC subsystem 215. For example, four inputs may be forwarded as channels A, B, C, and D (302) to ADC-1 212; two inputs may be forwarded as channels A and B (304 or 306) to either ADC-2 214 or ADC-N 216.

Diagram 300 further shows CPU 235 communicatively coupled to the FPGA 230 through the PCI interface (interconnect 236) and connected to the ADC sample clock 240 to control clock frequencies provided to the selected ADCs. The ADC sample clock 240 may alternatively be controlled by the FPGA 230. Digitized IF signals from the ADCs 210 may be provided to the FPGA 230 over a high-speed data transfer interface (HSI). For example, the HSI may be a standard interface according to Joint Electronic Device Engineering Council “JEDEC” standard JESD204B/C. The transferred data may be processed and/or stored by the FPGA 230. The FPGA 230 may control (e.g., select, activate) ADCs through a lower bandwidth interface such as a serial peripheral interface (SPI), which is a synchronous serial communication interface used for short-distance communication, primarily in embedded systems.

In some examples, the mixer 208 may down-convert and provide one input signal at a time to the ADCs 210. Thus, multiple input signals may be processed serially with time multiplexing. In other examples, the mixer 208 may be a mixing subsystem and include two or more mixers, which may down-convert multiple RF signals to IF signals simultaneously. Thus, multiple IF signals may be provided to one or more ADCs in parallel. Digitized signals from the ADCs may be provided, as mentioned herein, through the HIS to various input ports of the FPGA 230. If the FPGA 230 does not have sufficient number of input ports, a multiplexer (not shown) may be used between the ADCs 210 and the FPGA 230.

The FPGA 230 may select suitable ADC(s) within available ADCs 210 based on individual ADC characteristics. As mentioned above, multiple input signals may be received at a multiple channel test device (spectrum analyzer) with different frequencies and bandwidths. The signals may also be of different type (also referred to as technology) such as time division multiplexed, frequency division multiplexed, etc. Multi-channel ADCs typically convert each input channel sequentially using an input multiplexer.

Accordingly, different ADCs may be selected to convert different input signals to optimize accuracy depending on the input signal types, frequencies, and bandwidths. An ADC may be selected based on the frequency and bandwidth selected by the user. When the user enters the frequency and bandwidth of interest, an RF path and suitable ADC(s) may be selected by a matching table for optimal performance saved in the FPGA 230.

In some examples, an ADC selection based on an initial setting value may be arbitrarily determined by the manufacturer. For example, the manufacturer may select an ADC suitable for the most-used frequency and bandwidth in the market. In other examples, a user may select to use an ADC by a saved value at the next power-up of the test device 106 or to use the ADC set by the manufacturer.

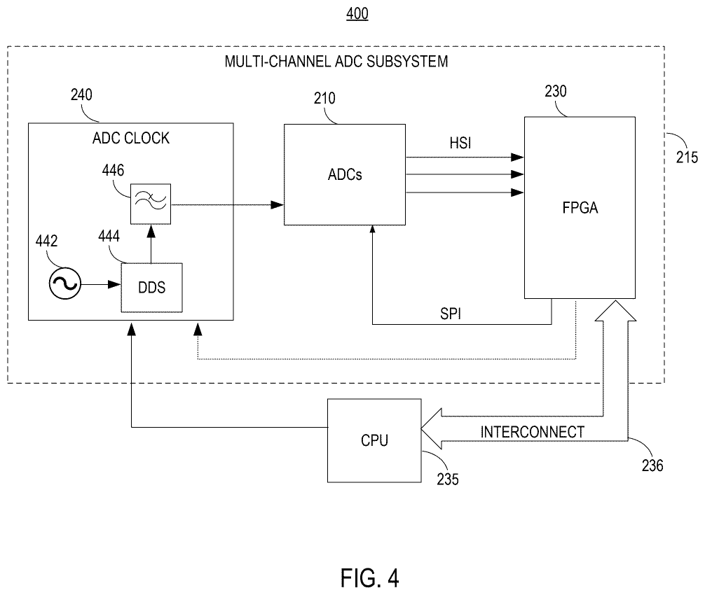

FIG. 4 illustrates a diagram 400 of the multi-channel ADC subsystem 215 managed by the FPGA 230 with (adjustable) ADC sample clock 240, according to examples described herein. Diagram 400 shows the multi-channel ADC subsystem 215 managed by the FPGA 230, such as any of the multi-channel ADC subsystems and the FPGAs discussed above. The multi-channel ADC subsystem 215 may include any number of multi-channel ADCs. The ADCs 210 may operate receiving clock frequency(ies) from the ADC sample clock 240, which may include, among other components, an oscillator 442, a direct digital synthesizer 444, and a low-pass or band-pass filter 446.

The CPU 235 may control the ADC sample clock 240 in providing respective clock signals to the selected ADCs. In some examples, the FPGA 230 may also control the ADC sample clock 240. The CPU 235 may further receive digitized (and/or processed) data from the FPGA 230 over PCI interface (interconnect 236).

As mentioned herein, the FPGA 230 may manage the multi-channel ADC subsystem 215 over SPI selecting one or more suitable ADCs based on the ADC characteristics, a frequency and a bandwidth of the input signals. In some examples, the FPGA 230 may also select particular inputs of an ADC instead of or in addition to the selection of ADCs. Once the ADC(s) have been selected, the FPGA 230 (or the CPU 235) may also set clock frequencies to be provided to the selected ADC(s) by the ADC sample clock 240.

It may be appreciated that, in some instances, implementation of a test device including a multi-channel ADC subsystem may varying noise levels that may be sub-optimal. Specifically, in some instances and as will be discussed in further detail below, implementation of an ADC subsystem with particular channel bandwidths and at particular frequency bands may produce noise levels that may inhibit operation of the test device.

For example, a test device that may be configured to test LTE telecommunications networks may typically support testing of five (5) to twenty (20) megahertz (MHz) bandwidth. Also, with regard to 5G New Radio (5G NR) telecommunications networks, the test device may typically be configured to support testing of one hundred (100) megahertz (MHz) bandwidth, and also four hundred (400) megahertz (MHz) bandwidth. It may be appreciated that operating in these various bandwidths and over various frequency bands may require varying noise performance implementations in test devices.

In some examples and as discussed above, a test device (e.g., the test device 106) may include a front end (e.g., the front end 202) that may have or be coupled to a mixer (e.g., the mixer 208) to down-convert an RF signal to create an intermediate frequency (IF) signal to be provided to an ADC subsystem for digitizing. In some examples, it may be beneficial to address noise performance issues for an IF signal via introduction of a balun.

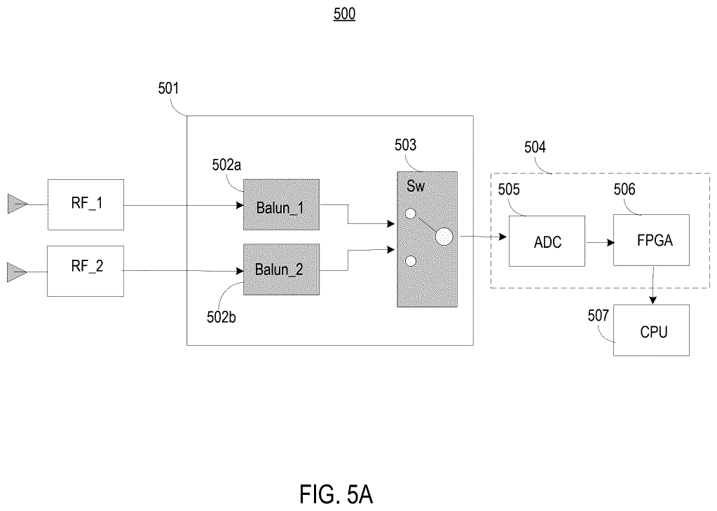

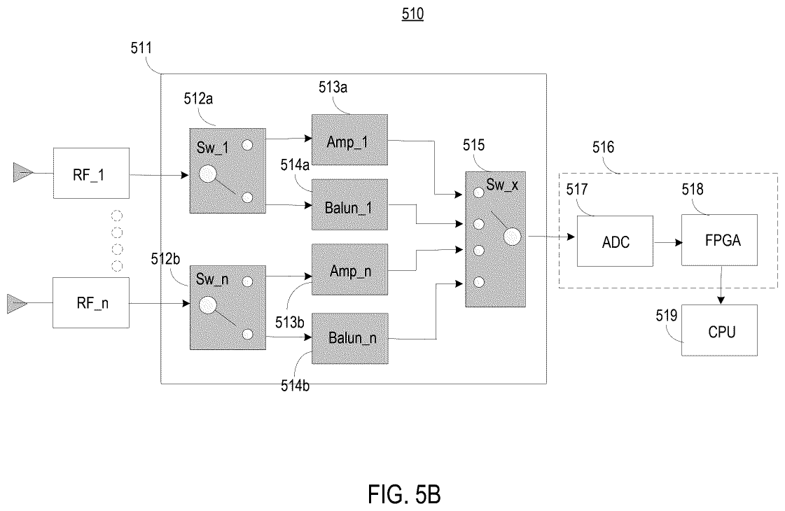

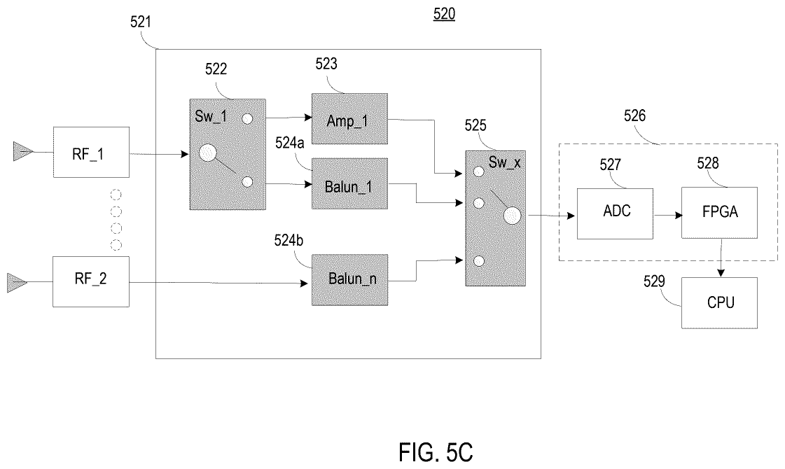

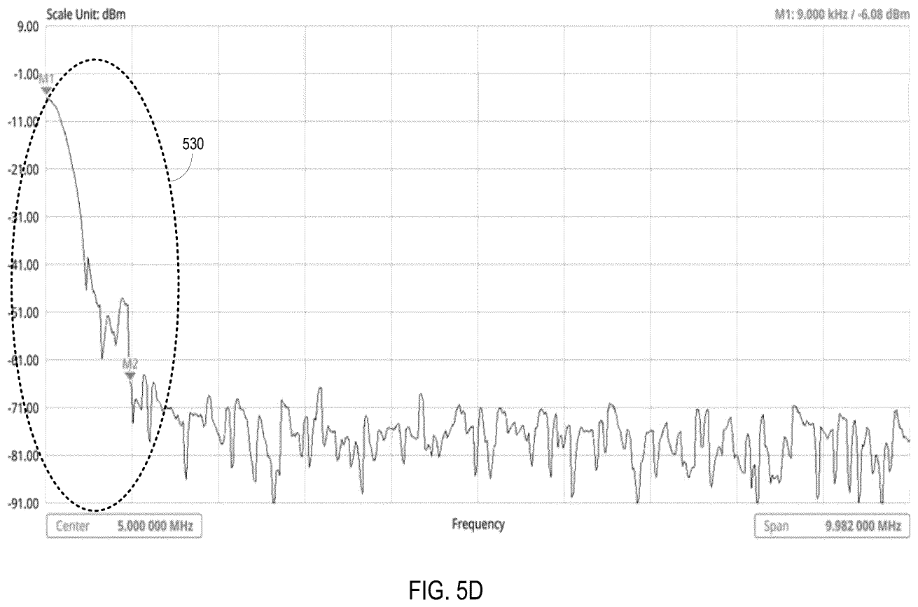

FIG. 5A illustrates a block diagram of major components of a test device 500 including a noise performance component 501, according to an example. As used herein, a “noise performance component” may include one or more elements of a test device configured to enable noise performance by reducing radio frequency interference (RFI) and minimizing noise pickup(s) from electrical sources.

In the example illustrated in FIG. 5A, the noise performance component 501 to receive one or more RF signals (e.g., an IF signal), where each of the one or more RF signals may be provided to a (respective) balun 502a, 502b. In some examples, the baluns 502a, 502b may provide noise reduction prior to forwarding to an ADC subsystem. Specifically, the respective baluns 502a, 502b may forward the IF signal(s) to the switch 503, which may forward the (switched) signal to a multi-channel ADC subsystem (e.g., similar to the multi-channel ADC subsystem 215). In some examples, the multi-channel ADC subsystem 504 may include a multi-channel ADC 505 and an FPGA 506. In some examples, the FPGA may transmit the signal to the CPU 507, as discussed above.

It may be appreciated that, in some instances, a test device may not address an entirety of a bandwidth with sufficient noise performance. For example, in some instances (e.g., for LTE telecommunications), implementation of a balun may not be suitable for lower bandwidths. Indeed, in some instances, for lower bandwidth (e.g., nine (9) megahertz (KHz) to two hundred (200) megahertz (KHz)), to enable better noise performance and/or proper forwarding of the IF signal (e.g., to an ADC), it may be beneficial to implement an amplifier instead of a balun.

FIG. 5B illustrates a block diagram of major components of a test device 510 including a noise performance component 511, according to an example. In some examples, the noise performance component 511 may receive one or more RF signals (e.g., an IF signal). In some examples, in some examples, the noise performance component 511 may receive one or more IF signals from a mixer (e.g., from the mixer 208), and may forward the one or more signals to an ADC subsystem (e.g., to the ADC subsystem 215). It may be appreciated that, in some examples, the noise performance component 511 may be incorporated with the mixer, while in other examples, the noise performance component 511 may be independent of (i.e., separate from) the mixer.

In some examples, the noise performance component 511 may be implemented to perform noise reduction for 5G communication signals. In particular, as discussed further below, the noise performance component 511 may be implemented for one hundred (100) megahertz (MHz) bandwidth (e.g., 5g communications).

In some examples, the noise performance component 511 may include one or more amplifiers and/or one or more baluns. In particular, in some examples, the noise performance component may include one or more switches to couple an IF signal to an amplifier (i.e., a first path), and to couple one or more IF signals to a balun (i.e., a second path). In some examples, a switch may implement one of a plurality of paths based on predetermined bandwidths.

So, in the example illustrated in FIG. 5B, depending on the bandwidth of the first signal, the switch 512a may provide the first signal to either the amplifier 513a or the balun 514a.

In some examples, for one hundred (100) megahertz (MHz) bandwidth, and for an input bandwidth of nine (9) kilohertz (KHz) to forty-four (44) gigahertz (GHz), the switch 512a may provide the input IF signals ranging from nine (9) kilohertz (KHz) to one (1) megahertz (MHz) (i.e., a “lower” input bandwidth) to the amplifier 513a. It may be appreciated that in other examples, the amplifier 513a may be configured to receive other bandwidths as well.

Also, in some examples, for one hundred (100) megahertz (MHz) bandwidth, and for an input bandwidth of nine (9) kilohertz (KHz) to forty-four (44) gigahertz (GHz), and for IF input bandwidths of one hundred thirty-five (135) megahertz (MHz) to two hundred thirty-five (235) megahertz (MHz) [or one hundred eighty five (185) megahertz (MHz) ±fifty (50) megahertz (MHz)] (i.e., the “higher” input bandwidth), the switch 512a may provide the input signals to the balun 514a. It may be appreciated that in other examples, the balun 514a may be configured to receive other bandwidths as well.

Similarly, for an nth input signal (RF_n), the switch 512b may provide the first signal to the amplifier 513b for lower input bandwidths, or to the balun 514b for higher input bandwidths. In some examples, each of the amplifiers 513a, 513b and/or baluns 514a, 514b may forward the noise-performance adjusted signal to a switch 515, which may then forward the noise-performance adjusted signal to multi-channel ADC subsystem 516 including a multi-channel ADC 517 and an FPGA 518. In some examples, the FPGA 518 may transmit the noise-performance adjusted signal to the CPU 519, as discussed above. In some instances, by implementing the noise performance component 511, better noise performance and dynamic range for a spectrum and signal analyzing test device may be achieved.

It may be appreciated that, in some noise performance instances, it may not be necessary for a test device 500 to address an entirety of a bandwidth. For example, in some instances (e.g., for 5G telecommunications), implementation of an amplifier may not be necessary for certain bandwidths.

FIG. 5C illustrates a block diagram of major components of a test device 520 including a noise performance component 521, according to an example. In some examples, the noise performance component 521 may receive one or more RF signals (e.g., IF signals). In particular, in some examples, the noise performance component 521 may receive one or more signals (e.g., one or more IF signals). Specifically, in some examples, the noise performance component may 521 may receive the one or more signals from a mixer (e.g., from the mixer 208), and may forward the one or more IF signals to an ADC subsystem (e.g., to the ADC subsystem 215). It may be appreciated that, in some examples, the noise performance component 521 may be incorporated with the mixer, while in other examples, the noise performance component 521 may be independent of (i.e., separate from) the mixer.

In some examples, the noise performance component 521 may be implemented to perform noise reduction for 5G communication signals. In some instances, the noise performance component 521 may be implemented, for example, for the 5G communication protocol. In particular, as discussed further below, the noise performance component 521 may be implemented for one hundred (100) megahertz (MHz) and four hundred (400) megahertz (MHz) bandwidths.

In some examples, the noise performance component 521 may be implemented as part of an ADC front end design, as discussed above, and may include one or more amplifiers and one or more baluns. In particular, in some examples, the noise performance component may include one or more switches to couple an IF signal to an amplifier (i.e., a first path), and/or to couple an IF signal to a balun (i.e., a second path). Also, in some examples, the noise performance component may implement the switch to a balun only as well (i.e., a “balun-only” path). In some examples, transmission over these paths may be based on predetermined bandwidths.

In some examples, a switch 522 may be implemented to couple a first sub-path for an RF signal to an amplifier, and to couple a second sub-path for an RF signal to a balun. In the example illustrated in FIG. 5C, depending on the bandwidth of the first signal, the switch 522 may provide the first signal to either the amplifier 523 or the balun 524a.

In some examples, for one hundred (100) megahertz (MHz) bandwidth, and for an input bandwidth of nine (9) kilohertz (KHz) to forty-four (44) gigahertz (GHz), the switch 522 may provide IF input signals ranging from nine (9) kilohertz (KHz) to one (1) megahertz (MHz) to the amplifier 523. It may be appreciated that in other examples, the amplifier 523 may be configured to receive other bandwidths as well.

Also, in some examples, for one hundred (100) megahertz (MHz) bandwidth, and for an input bandwidth of nine (9) kilohertz (KHz) to forty-four (44) gigahertz (GHz), the switch 522 may provide IF input bandwidths of one hundred thirty-five (135) megahertz (MHz) to two hundred thirty-five (235) megahertz (MHz) [or one hundred eighty five (185) megahertz (MHz) ±fifty (50) megahertz (MHz)] to the balun 524a. It may be appreciated that in other examples, the balun 524a may be configured to receive other bandwidths as well.

Furthermore, in some examples, for a second signal (RF_2), the second signal (RF_2) may be provided directly to the balun 524b, via a balun-only path. Specifically, for four hundred (400) megahertz (MHz) bandwidth, and for RF input frequencies of twenty-hour (24) gigahertz (GHz) to forty-four (44) gigahertz (GHz), IF bandwidths of two thousand seven hundred fifteen (2715) megahertz (MHz) to three thousand one hundred and fifteen (3115) megahertz (MHz) [or two thousand nine hundred fifteen (2915) megahertz (MHz) ±two hundred (200) megahertz (MHz)] may be forwarded (directly) to the balun 524b.

In some examples, the amplifier 523 and/or baluns 524a, 524b may forward a noise-performance adjusted signal to a switch 525. In some examples, the switch 525 may forward the noise-performance adjusted signal to multi-channel ADC subsystem 526 (e.g., similar to the multi-channel ADC subsystem 215), which may include a multi-channel ADC 527 and an FPGA 528. In some examples, the FPGA 528 may transmit the noise-performance adjusted signal to the CPU 529, as discussed above.

In some examples, implementation of the noise performance component 521 may provide a noise profile of a test device as illustrated in FIG. 5D. FIG. 5D illustrates a chart indicating mitigation of a noise level 530 as provided by the noise performance component 521, according to examples described herein.

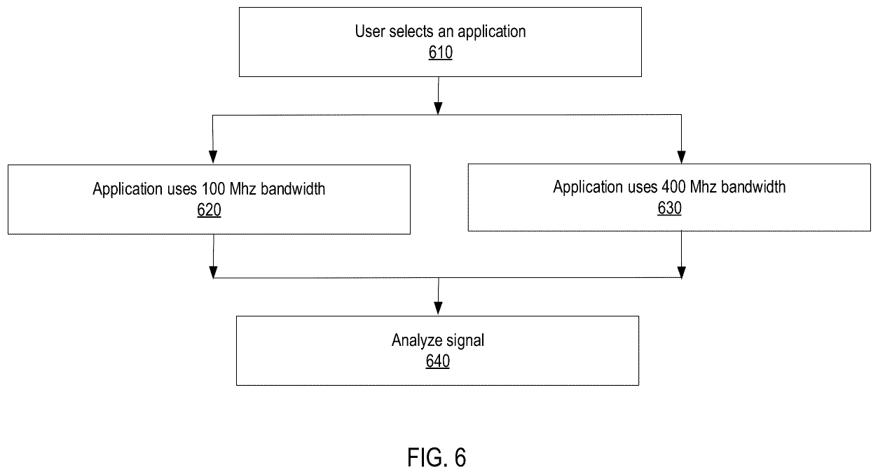

FIG. 6 illustrates a flow chart of a method 600 for employing a multi-channel ADC subsystem (e.g., the multi-channel ADC subsystem 215) managed by an FPGA (e.g., the FPGA 230) in a spectrum analyzer, according to examples described herein. The method 600 is provided by way of example, as there may be a variety of ways to carry out the method described herein. Although the method 600 is primarily described as being performed by the circuits of FIGS. 2-5, the method 600 may be executed or otherwise performed by one or more processing components of another system or a combination of systems. Each block shown in FIG. 6 may further represent one or more processes, methods, or subroutines, and one or more of the blocks (e.g., the selection process) may include machine readable instructions stored on a non-transitory computer readable medium and executed by a processor or other type of processing circuit to perform one or more operations described herein.

At 610, a user may select an application.

At 620, if the selected application may use one hundred (100) megahertz (MHz) bandwidth, it may be used an RF path of one hundred (100) megahertz (MHz) bandwidth (RF_1). In some examples, the user may set the frequency range with the center frequency and span. Furthermore, if the frequency range may be from nine (9) kilohertz (kHz) to one (1) megahertz (MHz), the switch (SW_1) may choose an amplifier (AMP_1) whose input may be a baseband signal. Also, in some examples, if the frequency range may be above one (1) megahertz (MHz), the switch (SW_1) may choose a balun (Balun_1) where the IF may be one hundred eighty-five (185) megahertz (MHz) ±fifty (50) megahertz (MHz).

At 630, if the selected application may use four hundred (400) megahertz (MHz) bandwidth, it may be used an RF path of four hundred (400) megahertz (MHz) bandwidth (RF_2). In some examples, the IF for Balun_2 may two thousand nine hundred fifteen (2915) megahertz (MHz) ±two hundred (200) megahertz (MHz).

At 640, a signal may be analyzed according to a selected application.

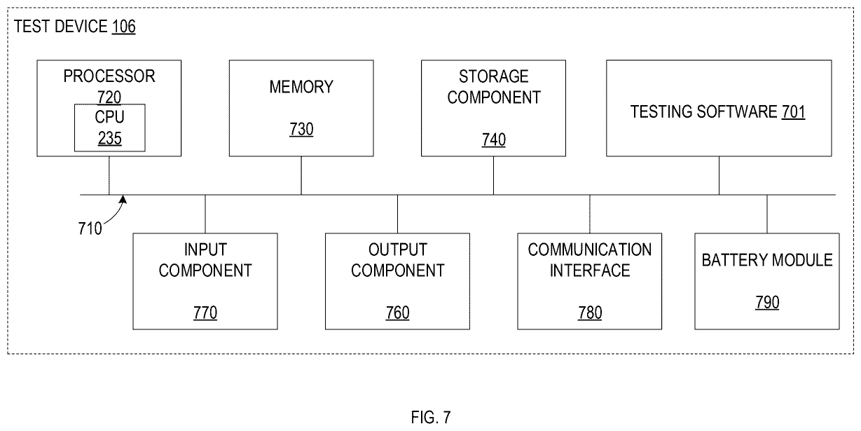

FIG. 7 illustrates a block diagram 700 of the test device 106, according to examples described herein. As shown in block diagram 700, the test device 106 may include the components of FIG. 2 and the components shown in FIG. 7. The test device 106 may include a bus 710, a processor 720, a memory 730, a storage component 740, an input component 770, an output component 760, a communication interface 780, and battery module 790.

Bus 710 includes a component that permits communication among the components of test device 106. Processor 720 may be implemented in hardware, firmware, or a combination of hardware and software. Processor 720 may include one or more of a central processing unit (CPU) 235, a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some examples, processor 720 may include one or more processors capable of being programmed to perform a function. Memory 730 may include one or more memories such as a random access memory (RAM), a read only memory (ROM), and/or another type of dynamic or static storage device (e.g., a flash memory, a magnetic memory, and/or an optical memory) that store information and/or instructions for use by processor 720.

Storage component 740 stores information and/or software related to the operation and use of test device 106. For example, storage component 740 may include a hard disk (e.g., a magnetic disk, solid state disk, etc.) and/or another type of non-transitory computer-readable medium.

Input component 770 may include a component that permits the test device 106 to receive information, such as via user input (e.g., a touch screen display, a keyboard, a keypad, a mouse, a button, a switch, and/or a microphone). Additionally, or alternatively, input component 770 may include a sensor for sensing information (e.g., a GPS component, an accelerometer, a gyroscope, and/or an actuator). Output component 760 includes a component that provides output information from the test device 106 (e.g., a display, a speaker, a user interface, and/or one or more light-emitting diodes (LEDs)). Output component 760 may include a display providing a GUI. Input component 770 and output component 760 may be combined into a single component, such as a touch responsive display, also known as a touchscreen.

Communication interface 780 may include a transceiver-like component (e.g., a transceiver and/or a separate receiver and transmitter) that enables test device 106 to communicate with other devices, such as via a wired connection, a wireless connection, or a combination of wired and wireless connections. Communication interface 780 may permit the test device 106 to receive information from another device and/or provide information to another device. For example, communication interface 780 may include an Ethernet interface, an optical interface, a coaxial interface, an infrared interface, an RF interface, a universal serial bus (USB) interface, a Wi-Fi interface, a cellular network interface, or the like.

Battery module 790 is connected along bus 710 to supply power to processor 720, memory 730, and internal components of the test device 106. Battery module 790 may supply power during field measurements by the test device 106. Battery module 790 may permit the test device 106 to be a portable.

The test device 106 may perform one or more processes described herein. The test device 106 may perform these processes by processor 720 executing software instructions (e.g., testing software 701) stored by a non-transitory computer-readable medium, such as memory 730 and/or storage component 740. A computer-readable medium is defined herein as a non-transitory memory device. A memory device includes memory space within a single physical storage device or memory space spread across multiple physical storage devices.

Software instructions may be read into memory 730 and/or storage component 740 from another computer-readable medium or from another device via communication interface 780. When executed, software instructions stored in memory 730 and/or storage component 740 may instruct processor 720 to perform one or more processes described herein. Additionally, or alternatively, hardwired circuitry may be used in place of or in combination with software instructions to perform one or more processes described herein. Thus, implementations described herein are not limited to any specific combination of hardware circuitry and software.

The test device 106 may include components other than shown. For example, the test device 106 may include a spectrum analyzer and power meter for performing tests described above. The number and arrangement of components shown in FIG. 7 are provided as an example. In practice, the test device 106 may include additional components, fewer components, different components, or differently arranged components than those shown in FIG. 7. Additionally, or alternatively, a set of components (e.g., one or more components) of the test device 106 may perform one or more functions described as being performed by another set of components of the test device 106.

While specific circuit configurations such as the arrangements of a number of components are shown in conjunction with the test device including a multi-channel ADC subsystem managed by an FPGA herein, the illustrated configurations are not intended to be limiting. A test device employing multi-channels ADCs may be implemented with other configurations and component values using the principles described herein.

While examples described herein are directed to configurations as shown, it should be appreciated that any of the components described or mentioned herein may be altered, changed, replaced, or modified, in size, shape, and numbers, or material, depending on application or use case, and adjusted for desired resolution or optimal measurement results.

It should be appreciated that the apparatuses, systems, and methods described herein may minimize and/or reduce analog-digital conversion errors and inaccuracies due to two or more signals with different characteristic being converted by the same ADC, and thereby facilitate more reliable and accurate RF measurements, specifically for input signals with different frequencies, bandwidths, and types. It should also be appreciated that the apparatuses, systems, and methods, as described herein, may also include, or communicate with other components not shown. For example, these may include external processors, counters, analyzers, computing devices, and other measuring devices or systems. This may also include middleware (not shown) as well. The middleware may include software hosted by one or more servers or devices. Furthermore, it should be appreciated that some of the middleware or servers may or may not be needed to achieve functionality. Other types of servers, middleware, systems, platforms, and applications not shown may also be provided at the backend to facilitate the features and functionalities of the testing and measurement system.

Moreover, single components may be provided as multiple components, and vice versa, to perform the functions and features described herein. It should be appreciated that the components of the system described herein may operate in partial or full capacity, or it may be removed entirely. It should also be appreciated that analytics and processing techniques described herein with respect to the optical measurements, for example, may also be performed partially or in full by other various components of the overall system.

It should be appreciated that data stores may also be provided to the apparatuses, systems, and methods described herein, and may include volatile and/or nonvolatile data storage that may store data and software or firmware including machine-readable instructions. The software or firmware may include subroutines or applications that perform the functions of the measurement system and/or run one or more application that utilize data from the measurement or other communicatively coupled system.

The various components, circuits, elements, components, and interfaces, may be any number of mechanical, electrical, hardware, network, or software components, circuits, elements, and interfaces that serves to facilitate communication, exchange, and analysis data between any number of or combination of equipment, protocol layers, or applications. For example, the components described herein may each include a network or communication interface to communicate with other servers, devices, components or network elements via a network or other communication protocol.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims—and their equivalents—in which all terms are meant in their broadest reasonable sense unless otherwise indicated.

1. A multi-channel analog-digital converter (ADC) subsystem for a radio frequency (RF) test device, comprising:
a noise performance component to receive one or more down-converted signals and generate one or more down-converted, noise performance-adjusted signals, wherein the noise performance component includes one or more amplifiers and one or more baluns;
a plurality of multi-channel ADCs to receive and convert the one or more down-converted, noise performance-adjusted signals and to one or more digital output signals; and
a field programmable gate array (FPGA) to receive the one or more digital output signals and forward the one or more digital output signals to a central processing unit (CPU).

2. The multi-channel ADC subsystem of claim 1, further comprising a first switch, wherein for one hundred (100) megahertz (MHz) bandwidth, and for an input bandwidth of nine (9) kilohertz (KHz) to forty-four (44) gigahertz (GHz), the first switch is to provide IF input signals ranging from nine (9) kilohertz (KHz) to one (1) megahertz (MHz) to a first amplifier of the one or more amplifiers, and wherein the first amplifier is to generate the one or more down-converted, noise performance-adjusted signals.

3. The multi-channel ADC subsystem of claim 1, further comprising a first switch, for one hundred (100) megahertz (MHz) bandwidth, and for an input bandwidth of nine (9) kilohertz (KHz) to forty-four (44) gigahertz (GHz), the first switch is to provide IF input bandwidths of one hundred thirty-five (135) megahertz (MHz) to two hundred thirty-five (235) megahertz (MHz) to a first balun of the one or more baluns, and wherein the first balun is to generate the one or more down-converted, noise performance-adjusted signals.

4. The multi-channel ADC subsystem of claim 1, further comprising a second balun to receive, for four hundred (400) megahertz (MHz) bandwidth, and for RF input frequencies of twenty-hour (24) gigahertz (GHz) to forty-four (44) gigahertz (GHz), IF bandwidths of two thousand seven hundred fifteen (2715) megahertz (MHz) to three thousand one hundred and fifteen (3115) megahertz (MHz), and wherein the second balun is to generate the one or more down-converted, noise performance-adjusted signals.

5. The multi-channel ADC subsystem of claim 4, further comprising a second switch to forward the one or more down-converted, noise performance-adjusted signals to a multi-channel ADC of the plurality of multi-channel ADCs.

6. The multi-channel ADC subsystem of claim 1, further comprising an ADC sample clock to provide a clock signal, and wherein the ADC sample clock comprises an oscillator, a direct digital synthesizer, and a filter.

7. The multi-channel ADC subsystem of claim 1, wherein the FPGA is further to select one or more inputs of a selected ADC to receive the one or more down-converted signals.

8. A test device to analyze radio frequency (RF) signals, comprising:
a front end to receive one or more RF signals and pre-process the received RF signals;
a mixer to down-convert the pre-processed RF signals;
a noise performance component to receive one or more down-converted signals from the mixer and to generate one or more down-converted, noise performance-adjusted signals, wherein the noise performance component includes one or more amplifiers and one or more baluns;
a multi-channel analog-digital converter (ADC) subsystem to receive the down-converted, noise performance-adjusted signals from the mixer and convert to digital output signals, wherein the multi-channel ADC subsystem comprises:
a plurality of multi-channel ADCs;
a field programmable gate array (FPGA) to select one or more ADCs among the plurality of ADCs; and
an ADC sample clock to provide a clock signal to the selected one or more ADCs; and
one or more operational subsystems to perform analytical operations on the digital output signals.

9. The test device of claim 8, wherein the front end comprises an attenuator and a filter.

10. The test device of claim 8, wherein the one or more operational subsystems include at least one of a display subsystem, an analysis subsystem, a fast Fourier transform (FFT) subsystem, or a storage subsystem.

11. The test device of claim 8, further comprising a first switch, wherein for one hundred (100) megahertz (MHz) bandwidth, and for an input bandwidth of nine (9) kilohertz (KHz) to forty-four (44) gigahertz (GHz), the first switch is to provide IF input signals ranging from nine (9) kilohertz (KHz) to one (1) megahertz (MHz) to a first amplifier of the one or more amplifiers, and wherein the first amplifier is to generate the one or more down-converted, noise performance-adjusted signals.

12. The test device of claim 8, further comprising a first switch, for one hundred (100) megahertz (MHz) bandwidth, and for an input bandwidth of nine (9) kilohertz (KHz) to forty-four (44) gigahertz (GHz), the first switch is to provide IF input bandwidths of one hundred thirty-five (135) megahertz (MHz) to two hundred thirty-five (235) megahertz (MHz) to a first balun of the one or more baluns, and wherein the first balun is to generate the one or more down-converted, noise performance-adjusted signals.

13. The test device of claim 8, further comprising a second balun to receive, for four hundred (400) megahertz (MHz) bandwidth, and for RF input frequencies of twenty-hour (24) gigahertz (GHz) to forty-four (44) gigahertz (GHz), IF bandwidths of two thousand seven hundred fifteen (2715) megahertz (MHz) to three thousand one hundred and fifteen (3115) megahertz (MHz), and wherein the second balun is to generate the one or more down-converted, noise performance-adjusted signals.

14. The test device of claim 8, wherein the FPGA comprises one or more digital processing circuitry to receive and process the digital output signals.

15. The test device of claim 8, wherein the test device is a spectrum analyzer.

16. A method, comprising:
receiving one or more down-converted signals from a mixer of a test device;
converting, by a noise performance component, the one or more down-converted signals from the mixer to one or more down-converted, noise performance-adjusted signals;
selecting, by a field programmable gate array (FPGA) of the test device, one or more analog-digital converters (ADCs) among a plurality of ADCs; and
converting the one or more down-converted, noise performance-adjusted signals to digital output signals using the one or more ADCs.

17. The method of claim 16, wherein for one hundred (100) megahertz (MHz) bandwidth, and for an input bandwidth of nine (9) kilohertz (KHz) to forty-four (44) gigahertz (GHz), further comprising providing IF input signals ranging from nine (9) kilohertz (KHz) to one (1) megahertz (MHz) to a first amplifier of an one or more amplifiers of the noise performance component, and wherein the first amplifier is to generate the one or more down-converted, noise performance-adjusted signals.

18. The method of claim 16, wherein for one hundred (100) megahertz (MHz) bandwidth, and for an input bandwidth of nine (9) kilohertz (KHz) to forty-four (44) gigahertz (GHz), further comprising providing IF input signals ranging from one hundred thirty-five (135) megahertz (MHz) to two hundred thirty-five (235) megahertz (MHz) to a first balun of one or more baluns of the noise performance component, and wherein the first balun is to generate the one or more down-converted, noise performance-adjusted signals.

19. The method of claim 18, wherein for four hundred (400) megahertz (MHz) bandwidth, and for RF input frequencies of twenty-hour (24) gigahertz (GHz) to forty-four (44) gigahertz (GHz), further comprising providing IF input signals ranging from two thousand seven hundred fifteen (2715) megahertz (MHz) to three thousand one hundred and fifteen (3115) megahertz (MHz) to a second balun of one or more baluns of the noise performance component, and wherein the second balun is to generate the one or more down-converted, noise performance-adjusted signals.

20. The method of claim 16, wherein a characteristic of each received RF signal comprises one or more of a frequency, a bandwidth, and a signal type.
